(19) United States
(12) Patent Application Publication
(10) Pub. No.: US 2025/0148184 A1
(43) Pub. Date: May 8, 2025

(54) INTEGRATED CIRCUIT DESIGN FLOW WITH LAYOUT ADJUSTMENT

(71) Applicant: Taiwan Semiconductor Manufacturing Company, Ltd., Hsinchu (TW)

(72) Inventors: Yung-Shun Chen, Hsinchu City (TW); Tzu-Ching Lin, Hsinchu City (TW); Shu-Chin Tai, Hsinchu City (TW); Amit Kundu, Hsinchu City (TW); Yung-Chow Peng, Hsinchu City (TW); Hung-Hsiang Lin, Hsinchu City (TW); Yi-Peng Weng, Hsinchu City (TW); Chung-Ting Lu, Hsinchu City (TW)

(73) Assignee: Taiwan Semiconductor Manufacturing Company, Ltd., Hsinchu (TW)

(21) Appl. No.: 18/502,377

(22) Filed: Nov. 6, 2023

(51) Int. Cl. G06F 30/392; G06F 30/398

(52) U.S. Cl. CPC G06F 30/392; G06F 30/398

(57) ABSTRACT

A computer readable medium comprising computer executable instructions for carrying out a method is disclosed. The method includes: generating a schematic of an integrated circuit including a plurality of components, each of the components associated with a format, the format indicating a matching group that represents a respective circuit functionality; merging a first device array layout, which corresponds to a first subset of the components that share a first matching group, and a second device array layout, which corresponds to a second subset of the components that share a second matching group, to form a third device array layout, in response to detecting that the first device array layout and the second device array layout share a same cell type; forming a first layer enclosing the third device array layout; inserting dummy patterns surrounding the first layer; and inserting a guard ring further surrounding the dummy patterns.

### BACKGROUND

The semiconductor industry has experienced continual rapid growth due to continuous improvements in the integration density of various electronic components (i.e., transistors, diodes, resistors, capacitors, etc.). For the most part, this improvement in integration density has come from repeated reductions in minimum feature size, allowing for the integration of more components into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of an integrated circuit design system, in accordance with some embodiments.

FIG. 2 illustrates an example flow chart of a method for operating the integrated circuit design system, in accordance with some embodiments.

FIG. 3 illustrates an example flow chart of a method for adjusting a layout, in accordance with some embodiments.

FIG. 4 illustrates a schematic design of an example integrated circuit, in accordance with some embodiments.

FIG. 5 illustrates an adjusted layout including an example CAD layer enclosing one or more merged device array layouts, in accordance with some embodiments.

FIG. 6 illustrates an adjusted layout including an example CAD layer enclosing one or more merged device array layouts, in accordance with some embodiments.

FIG. 7 illustrates an adjusted layout including dummy patterns around the example CAD layer of FIG. 6, in accordance with some embodiments.

FIG. 8 illustrates an adjusted layout including dummy patterns around a number of example CAD layers, in accordance with some embodiments.

FIG. 9 illustrates an adjusted layout including an example CAD layer enclosing one or more merged device array layouts, in accordance with some embodiments.

FIG. 10 illustrates an adjusted layout including an example CAD layer enclosing a number of interleaved device array layouts, in accordance with some embodiments.

FIG. 11 illustrates an adjusted layout including an example CAD layer enclosing a number of interleaved device array layouts, in accordance with some embodiments.

FIG. 12 illustrates an adjusted layout including an example CAD layer enclosing a number of device array layouts, in accordance with some embodiments.

FIG. 13 illustrates a schematic design of an example integrated circuit, in accordance with some embodiments.

FIG. 14 illustrates an adjusted layout including an example CAD layer enclosing a number of device array layouts, in accordance with some embodiments.

FIG. 15 illustrates an adjusted layout including several example CAD layers enclosing one or more device array layouts, respectively, in accordance with some embodiments.

FIG. 16 illustrates a block diagram of a computing device for implementing the integrated circuit design system shown in FIG. 1, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While features of integrated circuits shrink, modeling the impact of physical/layout effects up front in integrated circuit designs becomes popular. For integrated circuit designs, process design kits (PDKs) or process access kits (PAKs) have been commercially used to build up the integrated circuits. Generally, PDKs include geometric descriptions and device models of devices, such as transistors, diodes, resistors, capacitors, etc. Circuit design engineers translate PDKs to transistor netlists and/or gate-level netlists for circuit simulations, e.g., Simulation Program with Integrated Circuit Emphasis (SPICE) simulations. Based on the simulation results, circuit design engineers predict and/or modify the designs of the integrated circuits.

Existing SPICE methodologies, however, do not accurately predict the effect of certain component variations or mismatches of integrated circuit performance. As semiconductor feature size decreases, statistical variations in circuitry characteristics, caused by statistical variations in semiconductor processes can become increasingly severe. Some of the causes of such mismatch are edge effects, implantation and surface state charges, oxide effects, mobility effects, poly density gradient effects, etc. Among these causes, the poly density gradient effect (sometimes referred to as “DGE” effect) is sometimes one of the most crucial ones. For example, poly density gradients in adjacent regions (e.g., cells) of an array can cause unequal chemical mechanical planarization or polishing (CMP) polish rates on respective metal gates in the array or have non-uniform rapid thermal annealing (RTA). This, in turn, can influence device properties such as, but not limited to, device mobility and threshold voltage. As a result, the existing systems or methods for designing integrated circuits have not been entirely satisfactory in certain aspects.

The present disclosure provides various embodiments of systems and methods for designing integrated circuits that take into account the DGE effects. The disclosed system may be a part of a process design kit (PDK) implemented by an electronic design automation (EDA) tool. For example, the system, as disclosed herein, can identify a plural number of subsets of circuit components of an integrated circuit, where each subset shares a same matching group based on a schematic design of the integrated circuit. The disclosed system can generate the schematic design that indicates the matching group of each of the circuit components, which may be down to the unit of a transistor. The matching group can correspond to the circuit functionality of a corresponding circuit component. Upon identifying the respective matching groups of the subsets, the system can autonomously generate a first layer enclosing a layout of each of the subsets. Such a first layer may sometimes be referred to as a first computer-aided design (CAD) layer which may be a virtual or symbolic layout layer used by the EDA tool. In response to further identifying that two or more neighboring subsets (enclosed by the respective first CAD layers) share a same cell type, the system can merge such neighboring subsets and autonomously generate a second layer, or second CAD layer, enclosing the merged subsets. Based on a dimension of the second CAD layer, the system can autonomously insert dummy patterns according to the autonomously generated second CAD layer. For example, the system can add dummy patterns inside and/or outside the second CAD layer. Next, the system can further insert a guard ring surrounding the dummy patterns. With such a CAD layer generated, the system can quickly and accurately identify the boundary of active circuit components of the integrated circuit (or its schematic) and surround the boundary with dummy patterns. As such, the active circuit components of the integrated circuit can advantageously be immune from the DGE effects. Further, in the presence of the CAD layer(s) enclosing the active circuit components, a corresponding layout of the schematic design is compatible with various verification steps of the EDA tool such as, for example, Layout Versus Schematic (LVS) check, a Layout Parasitic Extraction (LPE) check, Design Rule Check (DRC), etc.

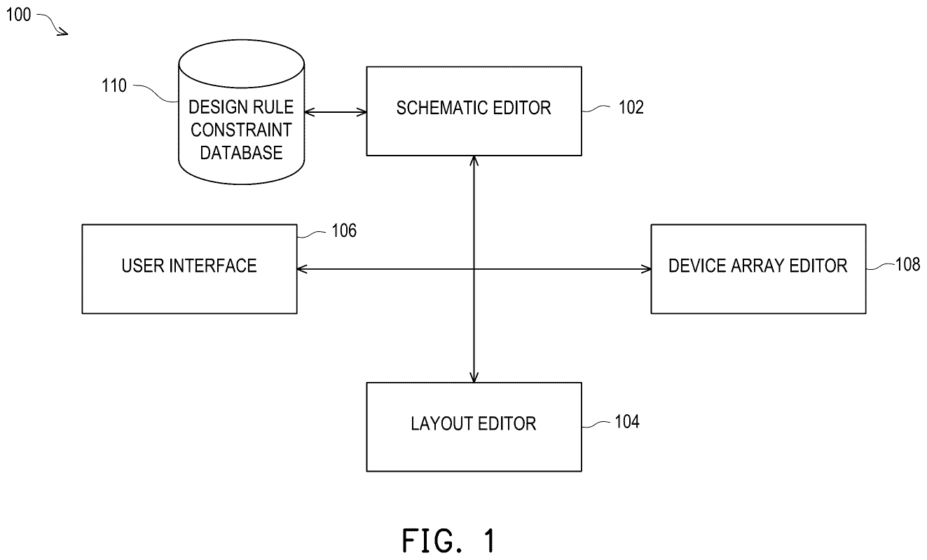

FIG. 1 illustrates a block diagram of an integrated circuit design system 100 for designing a DGE effect-aware integrated circuit, in accordance with various embodiments. The integrated circuit design system 100 may be a part of a PDK implemented by an EDA tool. It should be understood that the block diagram of FIG. 1 is simplified for illustrative purposes, and thus, the integrated circuit design system 100 can include any of various other components/blocks while remaining within the scope of the present disclosure.

The integrated circuit design system 100 makes it possible to reduce the number of iterations performed during the layout design process by providing a unique and complete design flow that autonomously merges a plural number of device array layouts and generates a CAD layer to enclose the merged device array layouts. The integrated circuit design system 100 also makes it possible to insert dummy patterns around the CAD layer, so as to verify the accuracy of an electrical design or performance of the layout compared to design specifications.

As shown, the integrated circuit design system 100 includes a schematic editor 102, a layout editor 104, a user interface 106, a device array editor 108, and a design rule constraint database 110 that are communicatively coupled to one another. In various embodiments of the present disclosure, the schematic editor 102, the layout editor 104, and the device array editor 108 may each include one or more sets of executable instructions for execution by at least one processor or similar device.

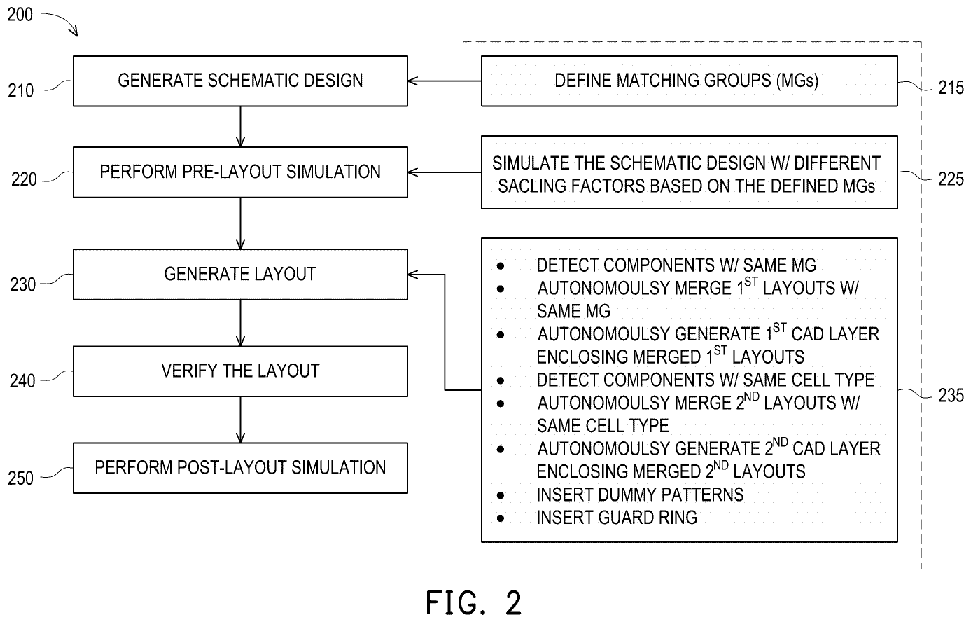

The schematic editor 102 can generate and edit the (e.g., circuit) schematic design of an integrated circuit that is being designed. The schematic editor 102 can perform a pre-layout simulation (e.g., a Simulation Program with Integrated Circuit Emphasis (SPICE) simulation) on the schematic design. According to various embodiments, the schematic editor 102 includes a set of executable instructions for generating or causing the pre-layout simulation of the schematic design. In other embodiments, a separate device (e.g., a simulator) in communication with the schematic editor 102 can generate the pre-layout simulation of the schematic design. The layout editor 104 can generate and edit layouts of the integrated circuits (e.g., device array layouts) in accordance with the schematic design generated by the schematic editor 102. The device array editor 108 can communicate with the layout editor 104 to autonomously merge one or more subsets of the device array layouts and generate a CAD layer to enclose the merged device array layouts. Upon generating the CAD layer, the device array editor 108 can communicate with the schematic editor 102 for inclusion in the circuit schematic of the integrated circuit for a post-layout simulation. The components of the integrated circuit design system 100 will be discussed in further detail below with respect to the method of FIG. 2.

The user interface 106 can receive and display the circuit schematic from the schematic editor 102, the layout from layout editor 104, and the device array layout from the device array editor 108, and any calculated circuit performance parameters. The user interface 106 can receive user inputs to adjust the circuit schematics, the device array layout, and the layout of the integrated circuit, and to select specific devices in order to display circuit performance parameters of specific devices selected by a user.

FIG. 2 illustrates a flow chart of an example method 200 for designing an integrated circuit, in accordance with various embodiments. The method 200 can be performed by the integrated circuit design system 100 of FIG. 1, and thus, the following discussion of the method 200 will sometimes be referred to the components of FIG. 1 (e.g., the schematic editor 102, layout editor 104, device array editor 108). It should be noted that the method 200 is merely an example and is not intended to limit the present disclosure. Accordingly, it is understood that additional operations may be provided before, during, and after the method 200 of FIG. 2, and that some other operations may only be briefly described herein.

The method 200 may start with operation 210 of generating the schematic design of an integrated circuit. In various embodiments, the schematic editor 102 can generate the schematic design based on a set of design rule constraints. The schematic editor 102 can query the design rule constraint database 110 for the set of applicable design rules and generate the schematic design of the integrated circuit. The schematic of the integrated circuit may include a plural number of circuit components. The circuit components may each be represented as a transistor, which can be implemented as a parametrized cell (PCell) by the integrated circuit design system 100, for example. In some other embodiments, the circuit component may be implemented as any of various other analog cells, while remaining within the scope of the present disclosure. The schematic of the integrated circuit may also include layout-dependent effect (LDE)-related information of each of the circuit components in a component description format (CDF). The LDE-related information can include dimensions of respective features (e.g., a number of its active regions which may be implemented as fin structures, a channel width, a channel length, a number of gate structures, a gate oxide thickness, etc.) of the circuit component.

In various embodiments, the LDE-related information can include a matching group (MG) of one or more of the circuit components, which may be defined through or otherwise received by the schematic editor 102 (e.g., operation 215). Specifically, the matching group may be associated with a corresponding circuit functionality. Such a matching group can be defined by a user of the integrated circuit design system 100. For example, the matching group may include one of: a current mirror, a differential pair, a biasing circuit, a distributed biasing circuit, or a clock sensitive circuit. In some embodiments, the LDE-related information can optionally include the size of a device array layout corresponding to the respective circuit component.

Next, the method 200 may proceed to operation 220 of performing a pre-layout simulation on the schematic design of the integrated circuit. In various embodiments, the schematic editor 102 can simulate the schematic design of the integrated circuit. The pre-layout simulation may be performed on a simulator, such as HSPICE® commercially available from Synopsys, Inc. (San Jose, Calif.), SPECTRE® commercially available from Cadence Design Systems, Inc. (San Jose, Calif.), or any commercially available pre-layout simulator. Upon completion of the pre-layout simulation, a layout of the integrated circuit, including one or more CAD layers that each define the boundary of certain active circuit components, can be generated collectively by the layout editor 104 and the device array editor 108, which will be discussed in detail below.

Further, in various embodiments, the schematic editor 102 can simulate the schematic design with respective scaling factors based on the matching groups of the schematic design (e.g., operation 225). For example, the schematic editor 102 can identify whether each of the circuit components is associated with a respective matching group. If so (i.e., associated with an assigned matching factor), the schematic editor 102 can run the pre-layout simulation (including a Monte Carlo simulation) with a relatively small factor; and if not (i.e., associated with no matching factor), the schematic editor 102 can run the pre-layout simulation (including a Monte Carlo simulation) with a relatively large factor.

Next, the method 200 may proceed to operation 230 of generating a layout for the integrated circuit. In various embodiments, the layout editor 104 and the device array editor 108 can cooperate to generate the layout based on the schematic design (generated at operation 210) and the pre-simulation result (generated at operation 220). For example, the layout editor 104 can first generate the layout based on the schematic design and the pre-simulation result using a platform, such as VIRTUOSO® commercially available from Cadence Design Systems, Inc. (San Jose, Calif.). Concurrently or subsequently, the device array editor 108 can update, adjust, or otherwise revise the layout by adding one or more CAD layers, e.g., through operation 235. Such a CAD layer can provide a symbolic boundary (e.g., recognized by one or more verification tools of the integrated circuit design system 100) for similar circuit components to be enclosed therein, which can advantageously help to separate any possible DGE effects outside the boundary.

For example, in operation 235, the device array editor 108 can detect, from the schematic design, the circuit components that share the same matching group. Upon detecting such circuit components, the device array editor 108 can communicate with the layout editor 104 and autonomously merge respective first device array layouts of these circuit components. Upon merging the first device array layouts as a corresponding one of a number of second device array layouts, the device array editor 108 can autonomously generate a first CAD layer enclosing each of the second device array layouts (i.e., merged first device array layouts). Next, the device array editor 108 can further detect, from the schematic design, the respective circuit components of one or more of the second device array layouts that share the same cell type. The same cell type may refer to as having the same cell identification, the same channel length, the same threshold voltage, or the same width of an active region. Upon detecting such second device array layouts, the device array editor 108 can autonomously merge these second device array layouts as a corresponding one of a number of third device array layouts. In response, the device array editor 108 can autonomously generate a second CAD layer enclosing each of the third device array layouts (i.e., merged second device array layouts).

Referring still to operation 235, once generating the second CAD layer, the device array editor 108 can insert, fill, or otherwise generate dummy patterns around the second CAD layer. Inserting dummy patterns is a technique for improving (e.g., thickness) uniformity in integrated circuits through the addition of the structures or the removal of existing structures. In general, the dummy patterns can include a number of fill patterns/structures similar to the active patterns/structures enclosed by the corresponding CAD layer. For example, the dummy patterns may include a number of fill structures that extend from the respective patterns/structures of the active patterns/structures enclosed by the corresponding CAD layer. As such, such dummy patterns may sometimes be referred to as identical dummy patterns (e.g., with respect to the patterns being enclosed by a CAD layer).

The insertion of dummy patterns may result in unwanted electrical effects. For example, adding dummy features alters the effective pattern density and line space. Removing features (oxide fill) alters the effective pattern density and line width. The impact of fill depends on the designed interconnect structure neighboring the fill (for metal dummy) or the designed interconnect structure itself (for oxide dummy). Adding metal fill modifies the coupling capacitance (C) between neighboring interconnects. Adding oxide dummy modifies the coupling capacitance (C) and interconnect resistance (R). The relative impact depends on the dimensions of the interconnect structures. The level of variations in R and C determine how the circuit is affected. Thus, by defining the (e.g., second) CAD layer and adding the dummy patterns around the CAD layer, impact of the insertion of these dummy patterns can be more accurately assessed through one or more verification tools (e.g., DRCs) of the integrated circuit design system 100.

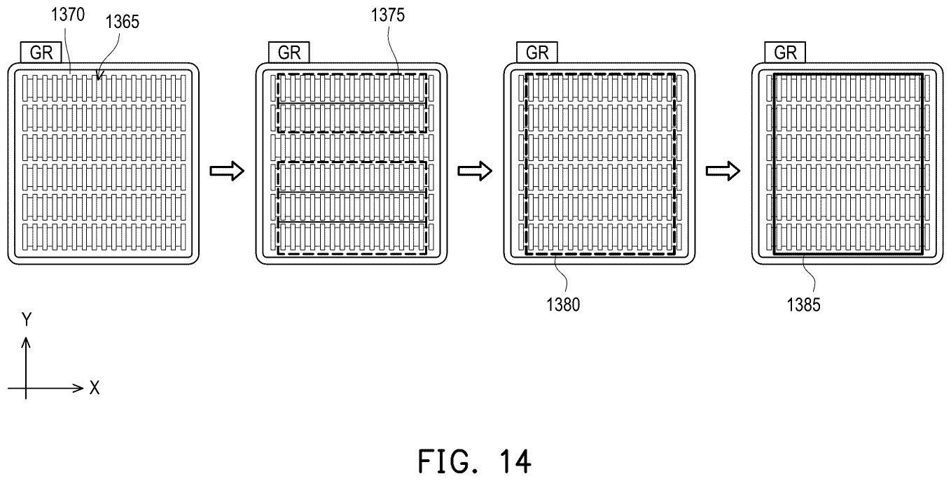

In some embodiments, the device array editor 108 can determine a dimension of the dummy patterns based on at least one of the design rule constraints (e.g., stored in the design rule constraint database 110) or a dimension of the second CAD layer. For example, the dummy patterns may be extended from each of the edges of the second CAD layer. As such, the dummy patterns can form a closed-loop enclosing the circuit components corresponding to the third device array layout (i.e., the merged second device layouts). And the dimension (e.g., width) of the dummy patterns may be determined by the device array editor 108 according to at least how much the second CAD layer extends in a first lateral direction and/or a second lateral direction, which will be discussed in further detail with respect to FIG. 14. Upon inserting the dummy patterns surrounding the second CAD layer, the device array editor 108 can insert a guard ring further surrounding the dummy patterns. As such, multiple device array layouts can share common guard ring.

Next, the method 200 may proceed to operation 240 of verifying the layout. In various embodiments, the integrated circuit design system 100 can include a number of verification tools to verify or otherwise check the layout. Examples of such checks include Design Rule Checks (DRCs), Layout-Versus-Schematic (LVS) checks (e.g., layout versus schematic comparison), Layout Parasitic Extraction (LPE) (e.g., a layout parameter extraction for MOS, resistor, capacitors, inductors, and/or other semiconductor devices), Resistance and Capacitance Extraction (RCX) (e.g., interconnect parasitic resistance and capacitance extractions for timing simulations), and other verification steps of checks.

After the layout (or the corresponding schematic design) passes the checks, the method 200 may proceed to operation 250 of performing a post-layout simulation on the schematic design of the integrated circuit. In various embodiments, the schematic editor 102 can simulate the schematic design of the integrated circuit. The post-layout simulation may be performed on a simulator, such as HSPICE® commercially available from Synopsys, Inc. (San Jose, Calif.), SPECTRE® commercially available from Cadence Design Systems, Inc. (San Jose, Calif.), or any commercially available pre-layout simulator.

In the post-layout simulation, various layout-dependent effects (e.g.,) are taken into account, so that generated circuit performance parameters reflect the actual circuit more accurately. The circuit performance parameters are then compared to design specification associated with the schematic design. If the circuit performance parameters meet the requirement of the design specification, the schematic design can be approved. Otherwise, the design process reverts back to the schematic generation and editing steps, which include the pre-layout simulation (operation 220), the layout creation (operation 230), the design verification (operation 240), and the post-layout simulation (operation 250) are repeated to modify the schematic design. The process is repeated until the circuit performance parameters meet the requirements of the design specification.

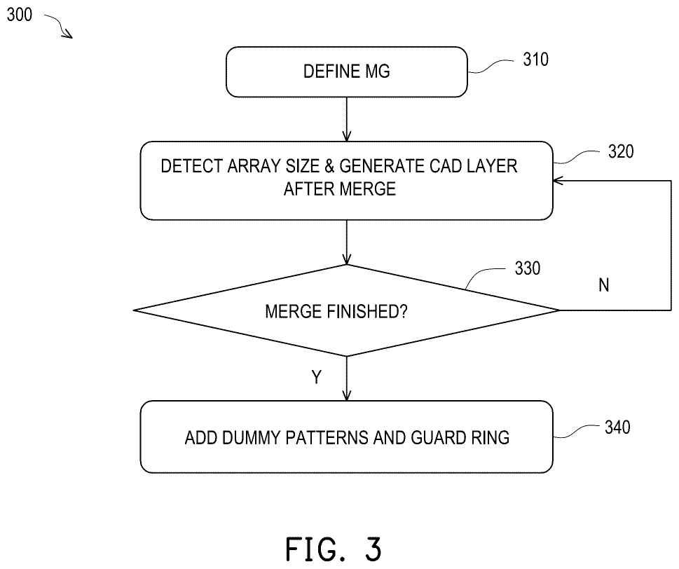

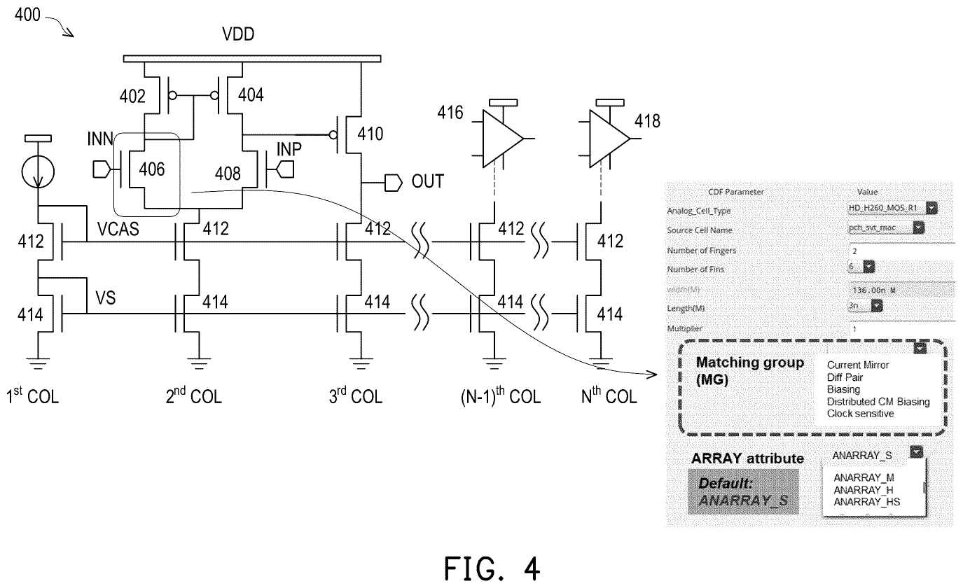

FIG. 3 illustrates a flow chart of a method 300 summarizing at least some of the operations described above (FIG. 2) that are performed by one or more components of the integrated circuit design system 100 (FIG. 1), in accordance with various embodiments. Further, FIGS. 4-8 collectively provide an example integrated circuit being designed through the method 300, and thus, the following discussion of the method 300 will be provided in conjunction with FIGS. 4-8. It should be noted that the method 300 is merely an example and is not intended to limit the present disclosure. Accordingly, it is understood that additional operations may be provided before, during, and after the method 300 of FIG. 3, and that some other operations may only be briefly described herein.

In various embodiments, the method 300 may start at operation 310 in which a matching group is defined for each of a plural number of circuit components of an integrated circuit. For example in FIG. 4, the schematic editor 102 of the integrated circuit design system 100 (FIG. 1) can generate a schematic design 400 including a plural number of circuit components, e.g., transistors or respective PCells recognized by the integrated circuit design system 100. Specifically, the example schematic design 400 includes circuit components 402, 404, 406, 408, 410, 412, 414, 416, 418, etc.

While generating the schematic design 400, the schematic editor 102 can define, receive, or identify a matching group assigned for each of the circuit components 402 to 414. The matching group can correspond to a functionality of the corresponding circuit component, in accordance with various embodiments. As a non-limiting example, the circuit components 402 and 404 may each be associated with a first matching group, e.g., a current mirror; the circuit components 406 and 408 may each be associated with a second matching group, e.g., a differential pair; and the circuit components 412 and 414 may each be associated with a third matching group, e.g., a distributed biasing circuit. Accordingly, the schematic editor 102 can specify or otherwise indicate the matching group in a corresponding CDF, as shown in FIG. 4. Alternatively or additionally, the schematic editor 102 can indicate other LDE-related information in the CDF such as, for example, a number of its active regions, a channel width, a channel length, a number of gate structures, a gate oxide thickness, etc.

Further, the schematic editor 102 can indicate the size of a device array layout associated with the corresponding circuit component. For example, in the CDF of FIG. 4, the schematic editor 102 can indicate a size of the device array layout for the circuit component 406 as one of: ANARRAY_S, ANARRAY_M, ANARRAY_H, or ANARRAY_HS; and when no size is indicated or specified (e.g., by a user), the schematic editor 102 may, by default, assign ANARRAY_S as the size of the device array layout. In some embodiments, the size of ANARRAY_S is less than the size of ANARRAY_M, the size of ANARRAY_M is less than the size of ANARRAY_H, and the size of ANARRAY_H is less than the size of ANARRAY_HS.

Next, the method 300 may proceed to operation 320 in which a size of the device array layout for each of the circuit components is detected, two or more of the device array layouts are merged, and a CAD layer is generated to enclose the merged device array layouts. The method 300 can proceed to operation 330 to determine whether there are more device array layouts to be merged. If so (e.g., one or more device array layouts mergeable), the method 300 may proceed to operation 340 of adding dummy patterns and a guard ring; and if not (e.g., no device array layout mergeable), the method 300 may revert back to operation 320. The method 300 may include one or more iterations from operations 320 to 330, in some embodiments.

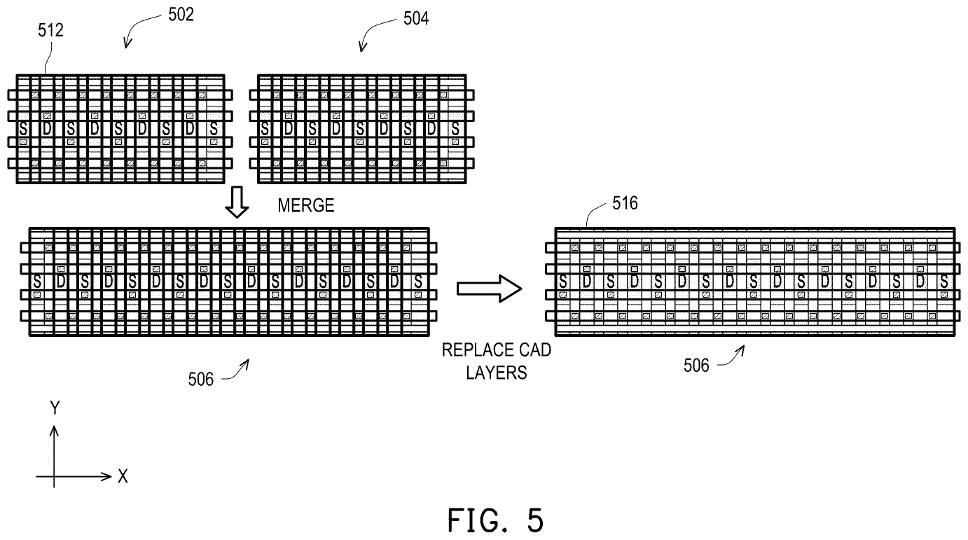

For example in FIG. 5, the device array editor 108 can communicate with the layout editor 104 to detect device array layouts 502 and 504 that correspond to the circuit components 402 and 404 of the schematic design 400, respectively. Each of the device array layouts 502 and 504 can include patterns for forming at least one active region (e.g., extending in the X-direction), one or more gate structures (e.g., extending in the Y-direction), one or more first interconnect structures (e.g., extending in the X-direction), one or more second interconnect structures (e.g., extending in the Y-direction), and one or more via structures, respectively.

In some embodiments, upon the device array layouts 502 and 504 being generated (e.g., by the layout editor 104), each of the device array layouts 502 and 504 includes one or more CAD layers, e.g., 512, the size of which may be specified in the LDE-related information in the CDF or be assigned by default. In response to detecting that the device array layouts 502 and 504 share the same matching group (e.g., as specified in the LDE-related information in the CDF), the device array editor 108 can update the layout by merging the device array layouts 502 and 504 as device array layout 506. Upon merging the device array layouts 502 and 504, the device array editor 108 can further update the layout by replacing the CAD layers 512 with a CAD layer 516 to enclose the merged device array layout 506.

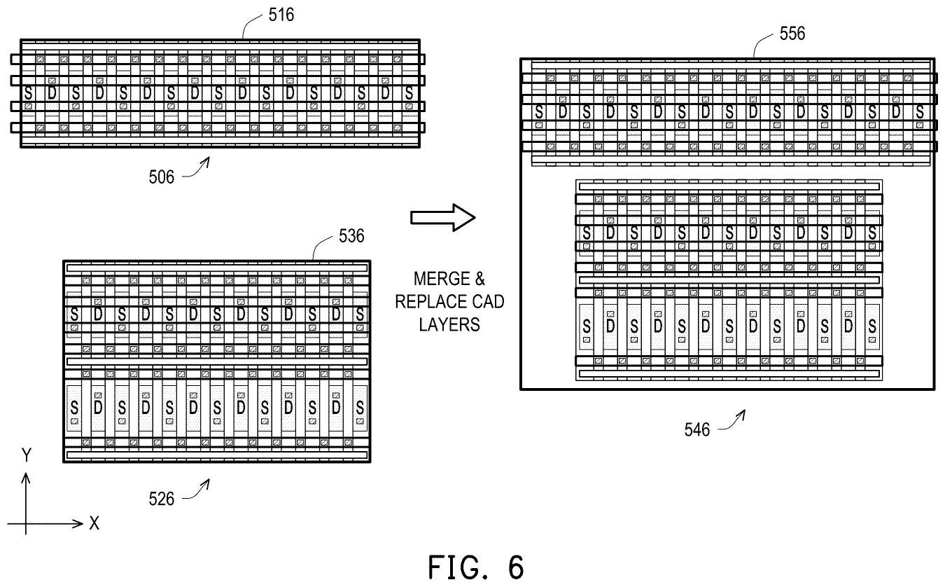

Further in FIG. 6, the device array editor 108 can detect another (e.g., merged) device array layout 526 that share the same cell type with the merged device array layout 506. The cell type can be specified in the LDE-related information in the respective CDFs. In some embodiments, the device array layout 526 may include respective device array layouts of the circuit components 406 and 408 (FIG. 4) being merged, and enclosed by a CAD layer 536. Further, the (merged) device array layout 506 and the (merged) device array layout 526 may be disposed immediately next to each other. As such, the device array editor 108 can further update the layout by merging the device array layouts 506 and 526 as device array layout 546, and replacing the CAD layers 516 and 536 as a CAD layer 556. The CAD layer 556 can enclose both of the device array layouts 506 and 526.

As described above, after merging a number of device array layouts that have respectively different matching groups yet share the same cell type and then generating a CAD layer to enclose them (e.g., creating the CAD layer 556), the device array editor 108 can further detect whether there are any other device array layouts to be merged and then enclosed. If yes, the device array editor 108 can follow the same operations as described in FIGS. 5-6. If not, the device array editor 108 can add dummy patterns around (e.g., inside and/or outside) the CAD layer 556 and then generate a guard ring surrounding the CAD layer 556.

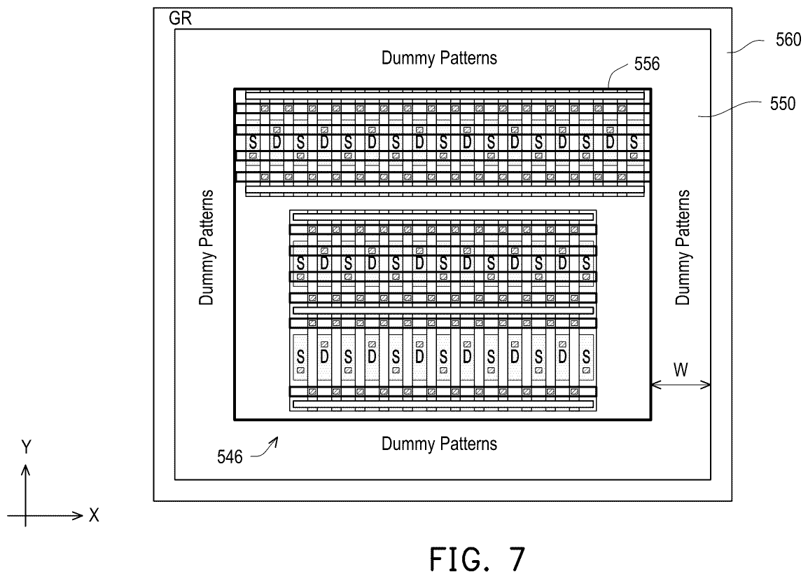

For example in FIG. 7, the device array editor 108 can add dummy patterns 550 around the CAD layer 556. Such dummy patterns may be “identical” to all the circuit components (e.g., 402, 404, 406, and 408) being surrounded to resolve mismatch issues due to the DGE effect. In some embodiments, the device array editor 108 may create the dummy patterns 550 by extending the respective patterns of the circuit components 402, 404, 406, and/or 408 from or across each of the edges of the CAD layer 556. Further, the device array editor 108 can extend the dummy patterns 550 with a width (W) in at least one of the X-direction or the Y-direction. In some embodiments, the device array editor 108 may determine the width W based on at least one of a dimension of the CAD layer 556 or various other LDE-related information of the circuit components (or device array layouts) enclosed. For example, such LDE-related information can include a channel length of the circuit components, a first spacing between adjacent active regions of the layout(s) along the X-direction, a second spacing between adjacent active regions of the layout(s) along the Y-direction, etc.

As a non-limiting example, if the CAD layer 556 is about the size of ANARRAY_S and the channel length of the enclosed circuit components has a minimum value reachable for a certain technology node, the device array editor 108 may determine the width W at a first value (e.g., in the unit of μm); if the CAD layer 556 is about the size of ANARRAY_M, the device array editor 108 may determine the width W at a second value (e.g., in the unit of μm); if the CAD layer 556 is about the size of ANARRAY_H, the device array editor 108 may determine the width W at a third value (e.g., in the unit of μm); and if the CAD layer 556 is about the size of ANARRAY_HS and the channel length of the enclosed circuit components has a maximum value reachable for a certain technology node, the device array editor 108 may determine the width W at a fourth value (e.g., in the unit of μm). In some embodiments, the fourth value of width W may be larger than the third value of width W, the third value of width W may be larger than the second value of width W, and the second value of width W may be larger than the first value of width W.

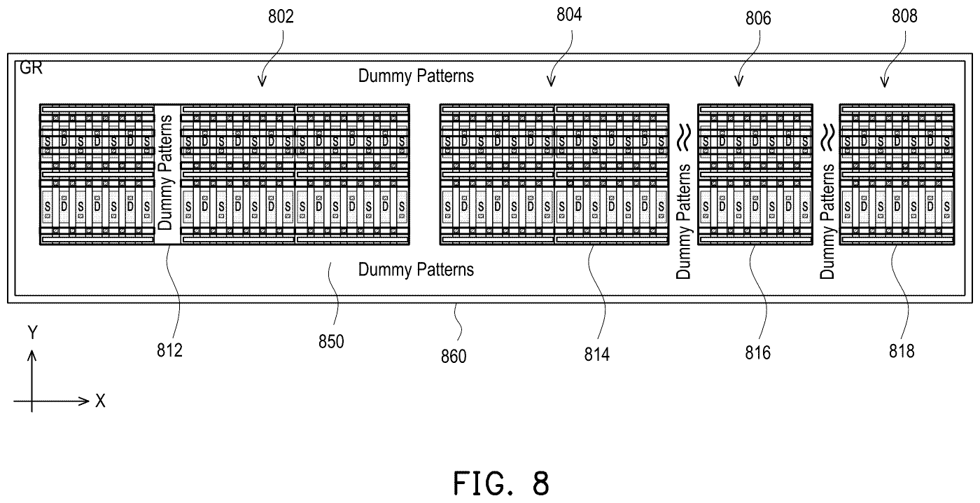

FIG. 8 illustrates another layout, corresponding to a portion of the schematic design 400 in FIG. 4, that is also updated by the device array editor 108. As shown in FIG. 8, the layout, after being updated by the device array editor 108, can include device array layouts 802, 804, 806, and 808 that correspond to the circuit components 406 and 408, 410, 416, and 418, respectively. Further, the device array editor 108 can generate CAD layers 812, 814, 816, and 810 to enclose the device array layouts 802, 804, 806, and 808, respectively.

In some embodiments, the device array editor 108 can further include respective device array layout(s) of one or more other circuit components in each of the CAD layers 812, 814, 816, and 810. Such other circuit components may belong to the same column of the circuit components (e.g., in the schematic design 400) originally enclosed by the corresponding one of the CAD layers 812, 814, 816, and 818. For example, the CAD layer 812 can include the device array layouts of the circuit components 412-414 in the second column; the CAD layer 814 can include the device array layouts of the circuit components 412-414 in the third column; the CAD layer 816 can include the device array layouts of the circuit components 412-414 in the (N-1)th column; and the CAD layer 810 can include the device array layouts of the circuit components 412-414 in the Nth column. Upon generating the CAD layers 812 to 818, the device array editor 108 can generate dummy patterns 850 to surround each of the CAD layers 812 to 818, and generate a guard ring 860 to further surround the dummy patterns 850. Alternatively or additionally, the device array editor 108 may insert dummy patterns inside one or more of the CAD layers, e.g., 812.

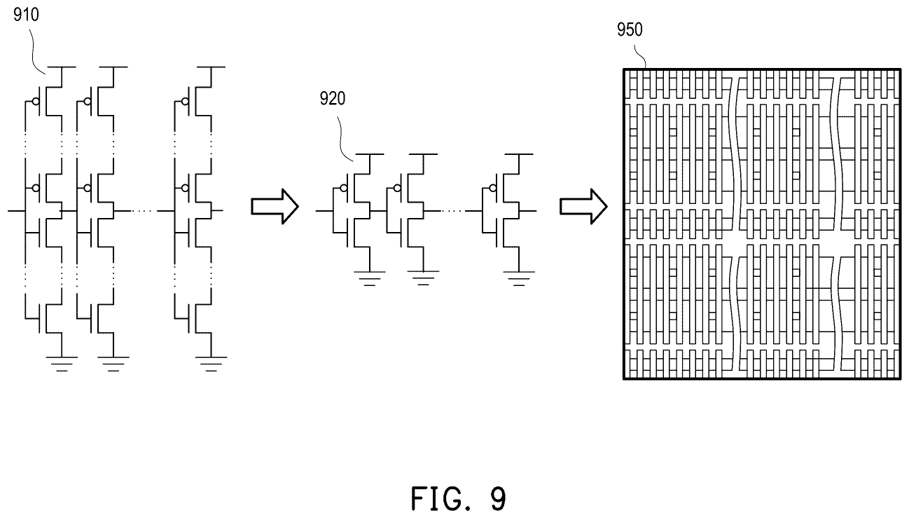

Referring again to FIG. 1, the device array editor 108 can further autonomously detect, recognize, or otherwise identify various other information (e.g., schematic information, LDE-related information, etc.) of a schematic design to update or adjust a corresponding layout. In some embodiments, these adjustments may be integrated into or supplemented to the method 300 of FIG. 3. Thus, some of reference numerals used above (e.g., FIGS. 1-3) may be continued being used in the following discussion of these adjustments. FIGS. 9, 10, 11, 12, 13, 14, and 15 illustrate examples of such adjustments, which will be discussed in further detail below, respectively.

In FIG. 9, upon communicating with the schematic editor 102 and/or the layout editor 104, the device array editor 108 may recognize some of the circuit components of a schematic design are constructed as a stacked gate transistor (e.g., 920), i.e., including a plural number of transistors (e.g., 910) sharing the same gate terminal, the same drain terminal, and the same source terminal by connecting their gate terminals together and connecting the drain terminal of one transistor to the source terminal of another adjacent transistor. As such, the device array editor 108 can autonomously generate a CAD layer 950 around (e.g., surrounding) respective device array layouts of the transistors 910, in some embodiments.

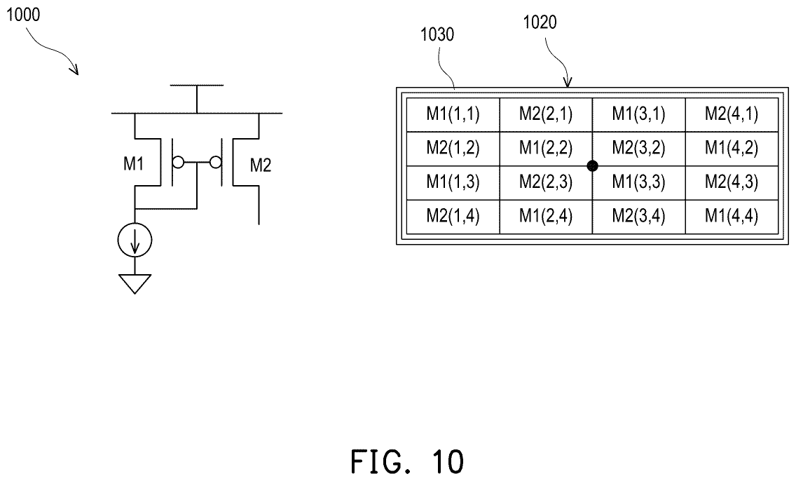

In FIG. 10, upon communicating with the schematic editor 102 and/or the layout editor 104, the device array editor 108 may recognize some of the circuit components of a schematic design (e.g., 1000) have respectively different LDE-related information. For example, circuit components M1 and M2 of the schematic design 1000 may have different numbers of active regions (thereby different driving powers). As such, the device array editor 108 can update a corresponding layout 1020 by rearranging respective device array layouts of the transistors M1 and M2, and autonomously generate a CAD layer 1030 around (e.g., surrounding) the layout 1020, in some embodiments. In some embodiments, the device array editor 108 can interleave the respective device array layouts of the transistors M1 and M2, causing the device array layouts to balance with one another. For example in FIG. 10, the device array layouts of the transistors M1 and M2 may be arranged in a checkboard manner, that is, each of the device array layouts of one of the transistors M1 and M2 has its four edges abutted with the device array layout of the other of the transistors M1 and M2, and its four corners placed with its own device array layout.

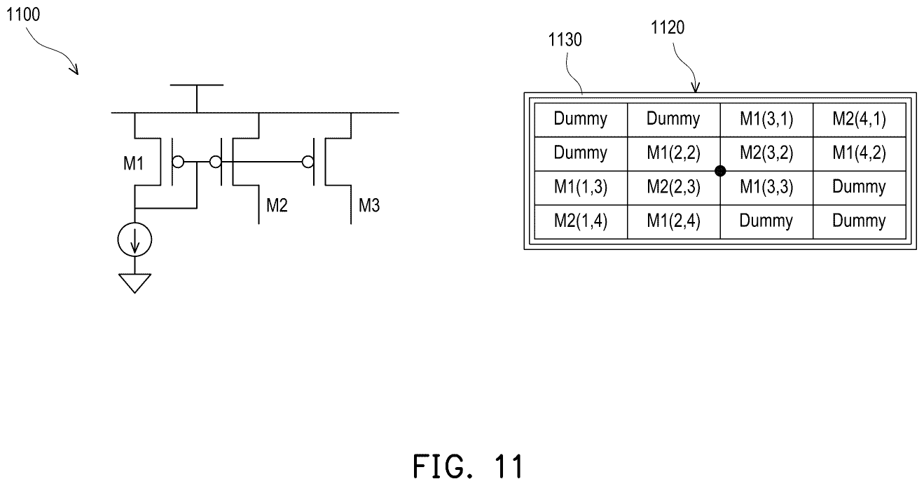

In FIG. 11, upon communicating with the schematic editor 102 and/or the layout editor 104, the device array editor 108 may recognize some of the circuit components of a schematic design (e.g., 1100) have respectively different LDE-related information. For example, circuit components M1 and M2-M3 of the schematic design 1100 may have different numbers of active regions (thereby different driving powers). As such, the device array editor 108 can update a corresponding layout 1120 by rearranging respective device array layouts of the transistors M1, M2, and M3, and autonomously generate a CAD layer 1130 around (e.g., surrounding) the layout 1120, in some embodiments. In some embodiments, the device array editor 108 can interleave the respective device array layouts of the transistors M1, M2, and M3, causing the device array layouts to balance with one another. For example in FIG. 11, along one of the diagonal lines of the layout 1120 (from the top left to the bottom right), two device array layouts of the transistor M1 may be symmetrically arranged with respect to a center of the layout 1120, further with dummy patterns inserted on the sides, respectively. Along another of the diagonal lines of the layout 1120 (from the bottom left to the top right), one device array layout of the transistor M2 and one device array layout of the transistor M3 may be symmetrically arranged with respect to the center of the layout 1120, further with additional device array layouts of the transistors M2 and M3 placed on the sides, respectively.

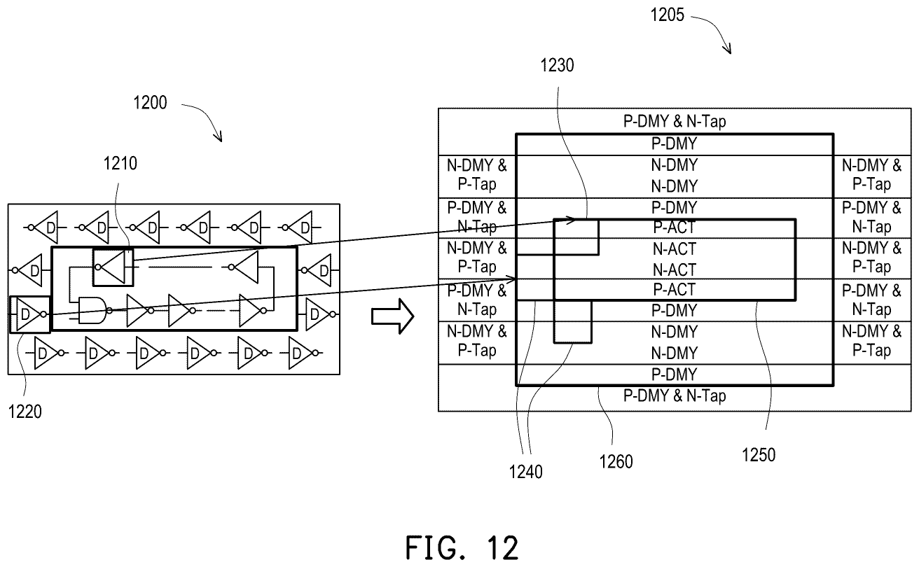

In FIG. 12, upon communicating with the schematic editor 102 and/or the layout editor 104, the device array editor 108 may recognize some of the circuit components of a schematic design (e.g., 1200) share the same schematic information. For example, multiple circuit components 1210 of the schematic design 1200 collectively serve as a sub-circuit, e.g., a ring oscillator. As such, the device array editor 108 can communicate with the schematic editor 102 to add a number of dummy circuit components 1220 (each of which is identical to at least one of the circuit components of the recognized sub-circuit), and update a corresponding layout 1205 by autonomously generate device array layouts 1240 (corresponding to the dummy circuit components 1220, respectively) to surround a CAD layer 1250 enclosing device array layouts 1230 of the circuit components 1210, in some embodiments. As shown, each of the device array layouts 1230 may consist of a first active region (P-ACT) and a second active region (N-ACT). In some embodiments, the device array editor 108 can update the layout 1205 through extending the active regions to form the device array layouts 1240 (e.g., P-DMY and N-DMY).

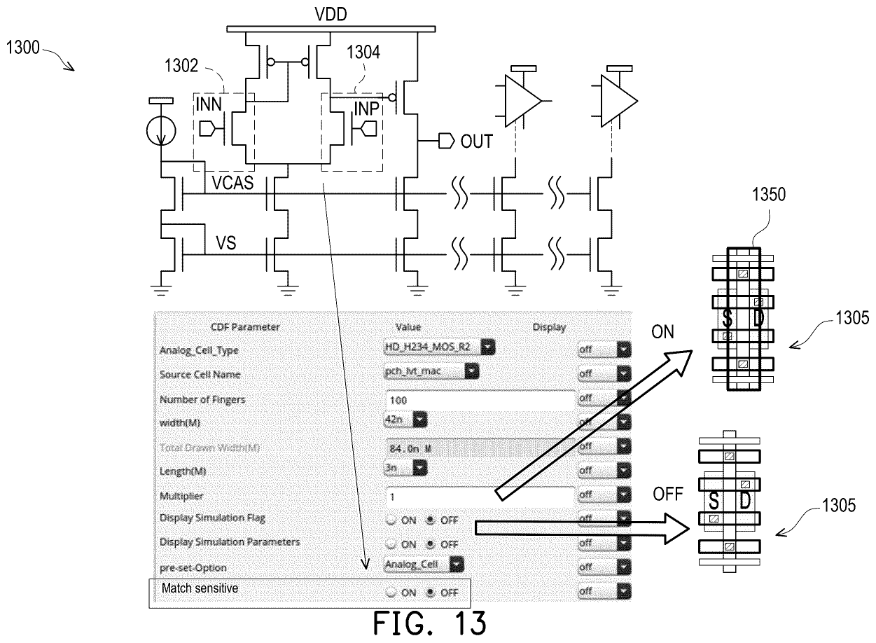

In FIG. 13, a schematic design 1300, including a plural number of circuit components (e.g., 1302, 1304), is shown. The schematic editor 102 can generate the schematic design 1300. In some embodiments, the schematic editor 102 can specify or otherwise indicate whether each of the circuit components is “match-sensitive” in a corresponding CDF, as shown in FIG. 13. Upon communicating with the schematic editor 102, the device array editor 108 may recognize such LDE-related information and autonomously generate a CAD layer to enclose corresponding device array layout. For example, if the match sensitive parameter is indicated as “ON,” the device array editor 108 can generate a CAD layer 1350 to enclose a device array layout 1305 of the circuit component 1302; and if the match sensitive parameter is indicated as “OFF,” the device array editor 108 may not generate a CAD layer to enclose the device array layout 1305. In various embodiments, the device array editor 108 can merge the device array layouts that share the same matching group (e.g., 1302 and 1304) and autonomously generate a CAD layer surrounding the merged layouts, as discussed above.

Upon merging the device array layouts as one or more merged layouts and enclosing each of them by a respective CAD layer, the device array editor 108 can extend such match-sensitive layouts in at least one of the X-direction or the Y-direction. For example in FIG. 14, merged layouts 1365 and their respective CAD layers 1370 are autonomously generated. The device array editor 108 can first extend each of the CAD layers 1370 in the X-direction as extended CAD layer 1375 to enclose one or more other device array layouts disposed next to the merged layout 1365 in the X-direction. In some embodiments, the device array editor 108 may extend the CAD layer 1370 until the edge of a total layout (e.g., a guard ring or an outermost cut pattern) is reached. Next, the device array editor 108 can further extend each of the extended CAD layers 1375 in the Y-direction as extended CAD layer 1380. Similarly, the device array editor 108 may extend the CAD layer 1375 until the edge of a total layout (e.g., a guard ring or an outermost active region) is reached. Accordingly, the device array editor 108 can generate a CAD layer 1385 using the extended CAD layer(s) 1380.

In some embodiments, to avoid over extending the CAD layer, the device array editor 108 can compare the size of a currently extended CAD layer with the size of a next extended CAD layer. Further, the device array editor 108 may consider the size of dummy patterns associated with the design constraints to determine whether to extend the currently extended CAD layer. As a non-limiting example, if the size of the currently extended CAD layer is less than a first threshold and a combination of the size of the currently extended CAD layer and the allowed size of the dummy patterns exceeds a second threshold, the device array editor 108 may stop extending the currently extended CAD layer. On the other hand, if the size of the currently extended CAD layer is less than the first threshold and the combination has not exceeded the second threshold, the device array editor 108 may further extend the currently extended CAD layer.

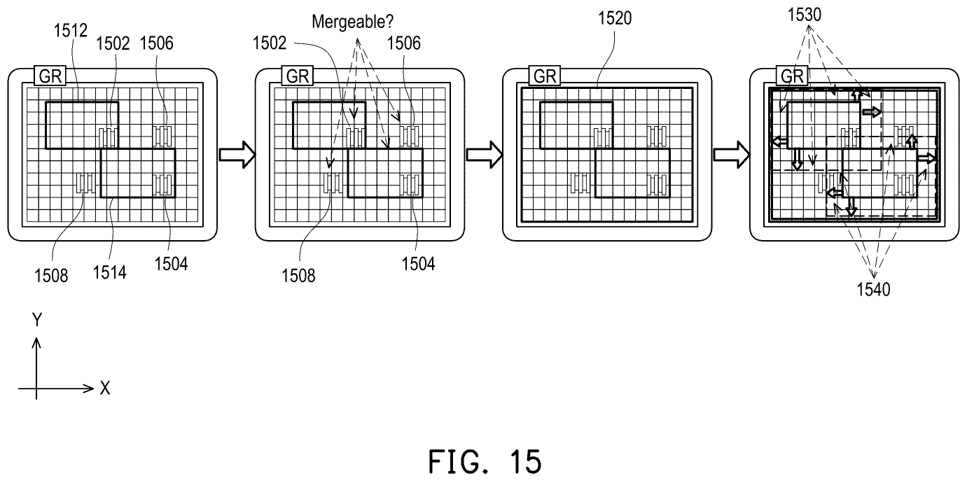

In FIG. 15, based on the above discussion, the device array editor 108 can identify one or more match-sensitive circuit components and generate CAD layers 1512 and 1514 to enclose respective device array layouts 1502 and 1504, respectively. The device array editor 108 can also identify one or more other non-match-sensitive circuit components and generate no CAD layer to enclose any of respective device array layout 1506 or 1508. Next, the device array editor 108 can determine whether to merge the device array layouts 1502 to 1508 based on their matching groups and/or cell types (e.g., operation 330 of FIG. 3). If so, the device array editor 108 may generate a CAD layer 1520 to enclose these device array layouts 1502 to 1508. However, in some embodiments, the device array editor 108 may insert dummy patterns based on the CAD layers 1512 and 1514 surrounding the device array layouts 1502 and 1504 of the match-sensitive circuit components, respectively, instead of the CAD layer 1520. As indicated in FIG. 15, dummy patterns can be inserted in regions 1530 surrounding the CAD layer 1512, and in regions 1540 surrounding the CAD layer 1514.

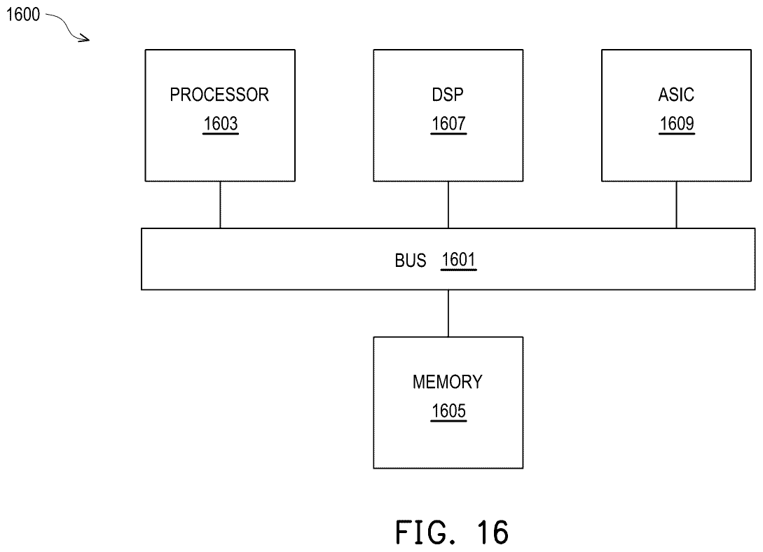

FIG. 16 illustrates a chip set or chip 1600 upon which or by which an embodiment is implemented. Chip set 1600 is programmed to design an integrated circuit having a device array free from a set of system design rule constraints, as described herein, and includes, for example, bus 1601, processor 1603, memory 1605, DSP 1607 and ASIC 1609 components.

The processor 1603 and memory 1605 are incorporated in one or more physical packages (e.g., chips). By way of example, a physical package includes an arrangement of one or more materials, components, and/or wires on a structural assembly (e.g., a baseboard) to provide one or more characteristics such as physical strength, conservation of size, and/or limitation of electrical interaction. It is contemplated that in certain embodiments the chip set 1600 are implemented in a single chip. It is further contemplated that in certain embodiments the chip set or chip 1600 is implemented as a single “system on a chip.” It is further contemplated that in certain embodiments a separate ASIC would not be used, for example, and that all relevant functions as disclosed herein would be performed by a processor or processors, e.g., processor 1603. Chip set or chip 1600, or a portion thereof, constitutes a mechanism for performing one or more steps of designing an integrated circuit having a device array free from a set of system design rule constraints.

In one or more embodiments, the chip set or chip 1600 includes a communication mechanism such as bus 1601 for passing information among the components of the chip set 1600. Processor 1603 has connectivity to the bus 1601 to execute instructions and process information stored in, for example, the memory 1605. In some embodiments, the processor 1603 is also accompanied with one or more specialized components to perform certain processing functions and tasks such as one or more digital signal processors (DSP) 1607, or one or more application-specific integrated circuits (ASIC) 1609. A DSP 1607 typically is configured to process real-world signals (e.g., sound) in real time independently of the processor 1603. Similarly, an ASIC 1609 is configurable to perform specialized functions not easily performed by a more general purpose processor. Other specialized components to aid in performing the functions described herein optionally include one or more field programmable gate arrays (FPGA), one or more controllers, or one or more other special-purpose computer chips.

In one or more embodiments, the processor (or multiple processors) 1603 performs a set of operations on information as specified by computer program code related to designing an integrated circuit having a device array free from a set of system design rule constraints. The computer program code is a set of instructions or statements providing instructions for the operation of the processor and/or the computer system to perform specified functions.

The processor 1603 and accompanying components have connectivity to the memory 1605 via the bus 1601. The memory 1605 includes one or more of dynamic memory (e.g., RAM, magnetic disk, writable optical disk, etc.) and static memory (e.g., ROM, CD-ROM, etc.) for storing executable instructions that when executed perform the steps described herein to design an integrated circuit having a device array free from a set of system design rule constraints. The memory 1605 also stores the data associated with or generated by the execution of the steps.

In one or more embodiments, the memory 1605, such as a random access memory (RAM) or any other dynamic storage device, stores information including processor instructions for designing an integrated circuit having a device array free from a set of system design rule constraints. Dynamic memory allows information stored therein to be changed by the integrated circuit design system 100. RAM allows a unit of information stored at a location called a memory address to be stored and retrieved independently of information at neighboring addresses. The memory 1605 is also used by the processor 1603 to store temporary values during execution of processor instructions. In various embodiments, the memory 605 is a read only memory (ROM) or any other static storage device coupled to the bus 1601 for storing static information, including instructions, that is not changed by the integrated circuit design system 100. Some memory is composed of volatile storage that loses the information stored thereon when power is lost. In some embodiments, the memory 1605 is a non-volatile (persistent) storage device, such as a magnetic disk, optical disk or flash card, for storing information, including instructions, that persists even when the integrated circuit design system 100 is turned off or otherwise loses power.

The term “computer-readable medium” as used herein refers to any medium that participates in providing information to processor 1603, including instructions for execution. Such a medium takes many forms, including, but not limited to computer-readable storage medium (e.g., non-volatile media, volatile media). Non-volatile media includes, for example, optical or magnetic disks. Volatile media include, for example, dynamic memory. Common forms of computer-readable media include, for example, a floppy disk, a flexible disk, hard disk, magnetic tape, any other magnetic medium, a CD-ROM, CDRW, DVD, any other optical medium, punch cards, paper tape, optical mark sheets, any other physical medium with patterns of holes or other optically recognizable indicia, a RAM, a PROM, an EPROM, a FLASH-EPROM, an EEPROM, a flash memory, any other memory chip or cartridge, or another medium from which a computer can read. The term computer-readable storage medium is used herein to refer to a computer-readable medium.

In one aspect of the present disclosure, a method for designing an integrated circuit is disclosed. The method includes generating a schematic of an integrated circuit that includes a plurality of components, each of the plurality of components associated with a format, the format indicating a matching group that represents a respective circuit functionality. The method includes generating a plurality of first device array layouts for the plurality of components, respectively, based on their respective matching groups. The method includes merging a first subset of the plurality of first device array layouts to form a second device array layout, in response to detecting that the first subset of the first device array layouts share a same first matching group. The method includes generating a first layer enclosing the second device array layout. The method includes merging a second subset of the plurality of first device array layouts to form a third device array layout, in response to detecting that the second subset of the first device array layouts share a same second matching group, the second matching group different from the first matching group. The method includes generating a second layer enclosing the third device array layout. The method includes merging the second device array layout and the third device array layout to form a fourth device array layout, in response to detecting that the second device array layout and the third device array layout share a same cell type. The method includes forming a third layer enclosing the fourth device array layout. The method includes inserting dummy patterns surrounding the third layer.

In another aspect of the present disclosure, a system for designing an integrated circuit is disclosed. The system includes at least one processor, and at least one memory including computer program code for one or more programs. The at least one memory and the computer program code are configured to, with the at least one processor, cause the system to: generate a schematic of an integrated circuit that includes a plurality of components, each of the plurality of components associated with a format, the format indicating a matching group that represents a respective circuit functionality; merge a first device array layout, which corresponds to a first subset of the plurality of components that share a first matching group, and a second device array layout, which corresponds to a second subset of the plurality of components that share a second matching group, to form a third device array layout, in response to detecting that the first device array layout and the second device array layout share a same cell type; form a first layer enclosing the third device array layout; insert dummy patterns surrounding the first layer; and insert a guard ring further surrounding the dummy patterns.

In yet another aspect of the present disclosure, a computer readable medium comprising computer executable instructions for carrying out a method for designing an integrated circuit is disclosed. The method includes: generating a schematic of an integrated circuit that includes a plurality of components, each of the plurality of components associated with a format, the format indicating a matching group that represents a respective circuit functionality; merging a first device array layout, which corresponds to a first subset of the plurality of components that share a first matching group, and a second device array layout, which corresponds to a second subset of the plurality of components that share a second matching group, to form a third device array layout, in response to detecting that the first device array layout and the second device array layout share a same cell type; forming a first layer enclosing the third device array layout; inserting dummy patterns surrounding the first layer; and inserting a guard ring further surrounding the dummy patterns.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, +20%, or +30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for designing an integrated circuit, comprising:
generating a schematic of an integrated circuit that includes a plurality of components, each of the plurality of components associated with a format, the format indicating a matching group that represents a respective circuit functionality;
generating a plurality of first device array layouts for the plurality of components, respectively, based on their respective matching groups;
merging a first subset of the plurality of first device array layouts to form a second device array layout, in response to detecting that the first subset of the first device array layouts share a same first matching group;
generating a first layer enclosing the second device array layout;
merging a second subset of the plurality of first device array layouts to form a third device array layout, in response to detecting that the second subset of the first device array layouts share a same second matching group, the second matching group different from the first matching group;
generating a second layer enclosing the third device array layout;
merging the second device array layout and the third device array layout to form a fourth device array layout, in response to detecting that the second device array layout and the third device array layout share a same cell type;
forming a third layer enclosing the fourth device array layout; and
inserting dummy patterns surrounding the third layer.

2. The method of claim 1, wherein the matching group includes one of: a current mirror, a differential pair, a biasing circuit, a distributed biasing circuit, or a clock sensitive circuit.

3. The method of claim 1, wherein the second device array layout is located immediately next to the third device array layout.

4. The method of claim 1, further comprising determining a dimension of the dummy patterns based at least on a set of system design rule constraints.

5. The method of claim 1, further comprising determining a dimension of the dummy patterns based at least on a dimension of the third layer.

6. The method of claim 1, wherein the cell type includes at least one of: a cell identification, a channel length, a threshold voltage, or a width of an active region.

7. The method of claim 1, further comprising inserting a guard ring further surrounding the dummy patterns.

8. The method of claim 6, further comprising:
prior to generating the first device array layouts, performing a first Simulation Program with Integrated Circuit Emphasis (SPICE) simulation on the schematic of the integrated circuit;
verifying the fourth device array layout through at least one of: Layout Versus Schematic (LVS) check, a Layout Parasitic Extraction (LPE) check, or a Design Rule Check (DRC); and
selectively performing, based on a result of the verification, a second SPICE simulation on the schematic of the integrated circuit.

9. A system for designing an integrated circuit, comprising:
at least one processor; and
at least one memory including computer program code for one or more programs, the at least one memory and the computer program code configured to, with the at least one processor, cause the system to:
generate a schematic of an integrated circuit that includes a plurality of components, each of the plurality of components associated with a format, the format indicating a matching group that represents a respective circuit functionality;
merge a first device array layout, which corresponds to a first subset of the plurality of components that share a first matching group, and a second device array layout, which corresponds to a second subset of the plurality of components that share a second matching group, to form a third device array layout, in response to detecting that the first device array layout and the second device array layout share a same cell type;
form a first layer enclosing the third device array layout;
insert dummy patterns surrounding the first layer; and
insert a guard ring further surrounding the dummy patterns.

10. The system of claim 9, wherein the matching group includes one of: a current mirror, a differential pair, a biasing circuit, a distributed biasing circuit, or a clock sensitive circuit.

11. The system of claim 9, wherein the second device array layout is located immediately next to the third device array layout.

12. The system of claim 9, wherein the system is further caused to determine a dimension of the dummy patterns based at least on a set of system design rule constraints.

13. The system of claim 9, wherein the system is further caused to determine a dimension of the dummy patterns based at least on a dimension of the first layer.

14. The system of claim 9, wherein the cell type includes at least one of: a cell identification, a channel length, a threshold voltage, or a width of an active region.

15. The system of claim 9, wherein each of the first subset of the components and/or each of the second subset of the components includes a plurality of transistors stacked on top of one another.

16. The system of claim 9, wherein, in the third device array layout, the first subset of the components and the second subset of the components are interleaved with one another.

17. The system of claim 9, wherein the system is further caused to:
generate a second layer enclosing the first device array layout;
extend the second layer in a first lateral direction until the guard ring is reached;
generate a third layer enclosing the second device array layout; and
extend the third layer in a second lateral direction until the guard ring is reached.

18. A computer readable medium comprising computer executable instructions for carrying out a method for designing an integrated circuit, the method comprising:
generating a schematic of an integrated circuit that includes a plurality of components, each of the plurality of components associated with a format, the format indicating a matching group that represents a respective circuit functionality;
merging a first device array layout, which corresponds to a first subset of the plurality of components that share a first matching group, and a second device array layout, which corresponds to a second subset of the plurality of components that share a second matching group, to form a third device array layout, in response to detecting that the first device array layout and the second device array layout share a same cell type;
forming a first layer enclosing the third device array layout;
inserting dummy patterns surrounding the first layer; and
inserting a guard ring further surrounding the dummy patterns.

19. The computer readable medium of claim 18, the method for designing the integrated circuit further comprising determining a dimension of the dummy patterns based on at least one of: a set of system design rule constraints or a dimension of the first layer.

20. The computer readable medium of claim 18, wherein the matching group includes one of: a current mirror, a differential pair, a biasing circuit, a distributed biasing circuit, or a clock sensitive circuit.
